(19) United States
(12) Patent Application Publication
(10) Pub. No.: US 2012/0127000 A1
(43) Pub. Date: May 24, 2012

(54) RECONFIGURABLE KEYBOARD HAVING ELECTRONICALLY RE-WRITABLE KEYS

(76) Inventor: Fathy Yassa, Soquel, CA (US)

(21) Appl. No.: 13/277,084

(22) Filed: Oct. 19, 2011

Related U.S. Application Data
(60) Provisional application No. 61/415,284, filed on Nov. 18, 2010.

(51) Int. Cl. H03M 11/00; B41J 5/10

(52) U.S. Cl. 341/22; 400/472

(57) ABSTRACT

In one embodiment, a reconfigurable keyboard having electronically writable keys receives input signals from a configurer that, for a first setting, results in a first displayed key layout, and in a second setting, results in a second displayed key layout. Each setting is associated with a specific functionality of the keyboard, for example a particular language. A configurer operates to execute the particular layouts and functionalities, and can be disposed on a portable device such as a memory stick for use with different computers and keyboards.

### PRIORITY CLAIM

This application claims the benefit of provisional patent application No. 61/415,284, filed Nov. 18, 2010, entitled “METHOD AND APPARATUS FOR RECONFIGURABLE KEYBOARD,” (Fathy Yassa), the contents of which are incorporated herein by reference in their entirety.

### TECHNICAL FIELD

The present disclosure relates generally to a computer keyboard in which the keys can be electronically written or re-written.

### BACKGROUND

Computer keyboard layouts often vary from country to country, making it difficult for a person from one country to use a computer keyboard in another country. Further complicating matters is the use of country specific diacritically-marked keys, modifier keys, and functions keys. A diacritical mark is an ancillary glyph added to a letter, or basic glyph. The main use of diacritics in the Latin alphabet is to change the sound value of the letter to which they are added. Examples from English are the diaeresis in naïve and Noël, which show that the vowel with the diaeresis mark is pronounced separately from the preceding vowel. By contrast the shift and Alt Gr or option keys, along with e.g. caps lock, control and alternative (alt) keys, are called modifier keys. There are also function keys, with various functions as determined by software.

Although there are a large number of different keyboard layouts used for different languages written in Latin script, they can be divided into three main families according to where the Q, A, Z, M, and Y keys are placed on the keyboard. These are usually named after the first six letters. While the core of the keyboard, the alphabetic section, remains fairly constant, and the numbers from 1-9 are almost invariably on the top row, keyboards differ vastly in:

the placement of punctuation characters,

which punctuation characters are included,

whether numbers are accessible directly or in a shift-state,

the presence and placement of accent dead keys and accented characters.

The actual mechanical keyboard is of the basic ISO, ANSI, or JIS type; functioning is entirely determined by operating-system or other software. It is customary for keyboards to be used with a particular software keyboard mapping to be engraved appropriately; for example, when the shift and numeric 2 keys are pressed simultaneously on a US keyboard; “@” is generated, and the key is engraved appropriately. On a UK keyboard this generates the double-quote character, and UK keyboards are so engraved.

The QWERTY keyboard is by far the most widespread layout in use, and the only one that is not confined to a particular geographical area. However, each country often makes regional changes to the layout.

Similarly, there are a plethora of non-QWERTY keyboards available for Latin scripts including the Dvorak, Colemak, JCUKEN, Neo, and Turkish.

Additionally, there are keyboards for non-Latin scripts such as Arabic and Greek as well as East Asian languages such as Japanese and Taiwanese.

These varying keyboards present a difficulty for international travelers who need to use a computer but will have difficulty utilizing a foreign keyboard.

The functional layout of the keyboard refers to the mapping between the physical keys and software events, such as the “A” key and the letter “A” appearing on the screen. Usually the functional layout is set to match the visual layout of the keyboard being used, so that pressing a key will produce the expected result, corresponding to the legends on the keyboard. However, most operating systems have software that allows the user to switch between functional layouts, such as the language bar in Microsoft Windows. For example, a user with a Swedish keyboard who wishes to type more easily in German may switch to a functional layout intended for German—without regard to key markings—just as a Dvorak touch typist may choose a Dvorak layout regardless of the visual layout of the keyboard used. The visual layout of any keyboard can also be changed by replacing its keys or attaching labels to them, such as to change an English-language keyboard from the common QWERTY to the Dvorak layout, although for touch typists, the placement of the tactile bumps on the home keys is of more practical importance than that of the visual markings.

Functional layouts can be redefined or customized within the operating system, by reconfiguring the operating system keyboard driver, or with a use of a separate software application. Transliteration is one example of that whereby letters in other language get matched to visible Latin letters on the keyboard by the way they sound. Thus, touch typist can type various foreign languages with visible English-language keyboard only. Alternatively, mixed hardware-to-software keyboard extensions exist to overcome above discrepancies between functional and visual layouts. A user applies keyboard stickers with an extra imprinted language alphabet and adds another keyboard layout via language support options in the operating system.

The current state of the art, e.g. rearranging keys or adding stickers are suboptimal solutions to the problem of customizing keyboards. Physically rearranging keys is a time consuming task, not suited for shared computers, and increases the likelihood of lost or broken keys. Similarly, adding stickers to keys remains time-consuming, cannot be done on shared computers or computers not owned by the user, etc.

### OVERVIEW

Described herein is a reconfigurable keyboard that includes one or more input connections and one or more electronically writable keys each coupled to a corresponding input connection and each having a display surface operative to display a plurality of symbols simultaneously or non-simultaneously based on a write signal received at the corresponding input connection.

Also described herein is a configurer for configuring a reconfigurable keyboard having one or more input connections and one or more electronically writable keys each coupled to a corresponding input connection and each having a display surface operative to display a plurality of symbols simultaneously or non-simultaneously based on a write signal received at the corresponding input connection. The configurer includes a memory operative to store one or more settings, a writer operative to issue write signals to input connections of the keys of the reconfigurable keyboard as a function of a selected one of the one or more settings, and an interpreter operative to interpret activation of keys of the reconfigurable keyboard as a function of the selected one of the one or more settings.

Also described herein is a system that includes a reconfigurable keyboard and a configurer. The reconfigurable keyboard has one or more input connections, and one or more electronically writable keys each coupled to a corresponding input connection and each having a display surface operative to display a plurality of symbols simultaneously or non-simultaneously based on a write signal received at the corresponding input connection. The configurer has a memory operative to store one or more settings, a writer operative to issue write signals to input connections of the keys of the reconfigurable keyboard as a function of a selected one of the one or more settings, and an interpreter operative to interpret activation of keys of the reconfigurable keyboard as a function of the selected one of the one or more settings.

Also described herein is a method for selectively configuring the operation of a keyboard having electronically writable keys. The method includes selecting a first setting, issuing to a first set of one or more keys of the keyboard write signals that cause each key of the first set to display at least one symbol that is a function of the first setting, associating activation of the keys of the first set with a first functionality of the keyboard that is a function of the first setting, selecting a second setting, issuing to the first set of one or more keys of the keyboard write signals that cause each key of the first set to display at least one symbol that is a function of the second setting, and associating activation of the keys of the first set with a second functionality of the keyboard that is a function of the second setting.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIG. 1 is a schematic diagram of a keyboard 100 having a plurality of keys 102 that are actuatable by a user;

FIG. 1a is diagram showing an embodiment in which each key is provided with an associated memory;

FIG. 2 is a block diagram showing a system for selectively configuring a keyboard; and

FIG. 3 is a flow diagram of a method 300 for selectively configuring the operation of a keyboard having electronically writable keys.

### DESCRIPTION OF EXAMPLE EMBODIMENTS

Example embodiments are described herein in the context of a reconfigurable keyboard having electronically rewritable keys. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used to the extent possible throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In accordance with this disclosure, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Eraseable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card, paper tape and the like) and other types of program memory.

The term “exemplary” is used exclusively herein to mean “serving as an example, instance or illustration.” Any embodiment described herein as “exemplary” is not necessarily to be construed as preferred or advantageous over other embodiments.

The arrangements described herein utilize an exemplary keyboard with visually dynamic lettering to automatically match the functional layout of the keyboard with the visual layout. The solution herein described is to populate a keyboard with keys in which the displayed letter on the key can be electronically changed through software running on the computer. The keys include one or more materials that can be visually configured such as LEDs, LCDs, liquid ink, or the like.

In one embodiment, the user selects a preferred key layout from the computer, using for example a mouse, keyboard, touchscreen, or toggle switch or the like. The computer then reconfigures both the functional and visual layouts to be consistent with the desired keyboard layout. In a second embodiment, the user stores the keyboard programming information on any input/output device such as a USB drive, or media device such as a CD room which may be uploaded into the system and configures the keys. For purposes of this disclosure, a computer can be any machine that receives input through a keyboard, and can include a desktop device, laptop device, PDA (personal digital assistant), smart phone, cellular telephone, and the like.

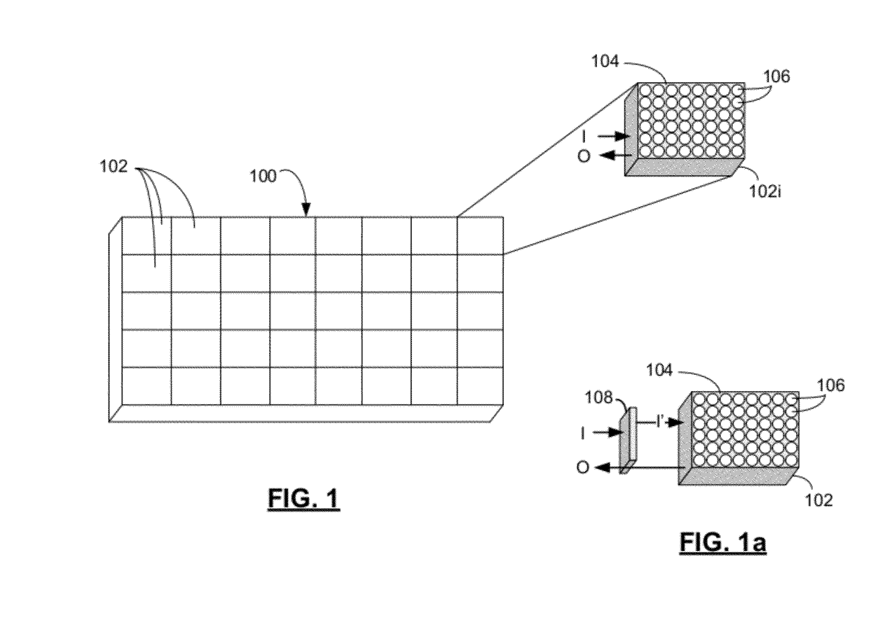

FIG. 1 is a schematic diagram of a keyboard 100 having a plurality of keys 102 that are actuatable by a user. In a mechanical embodiment, the keys are depressed by the fingers of a user (not shown). This depression is detected electronically, and a signal indicating the depression is sent to the computing device (not shown) to which the keyboard is connected via an output connection O. Output connection O can be in the form of a wire, PCB trace, or any conventional connection. The computing device can be separate from the keyboard 100, as in the case of a desktop computer, or it can be integral therewith, as in the case of a laptop computer, PDA, cellular telephone or smart phone, or the like.

Considering one of the keys 102i, it has at least one surface, 104, that is electro-optically re-writable based on write signals received by the keyboard 100, and specifically, by the key 102i itself, via input connection I. Input connection I can be in the form of an individual or a bundle of wires, PCB traces, or any conventional connection. In addition, while described as separate, the I/O connections of each key 102 may be implemented on the same electrical line and time-multiplexed as necessary. Surface 104 may comprise a plurality of individually addressable and writable elements 106 such as LEDs configured to emit the same or different color light, whose activation can be coordinated to indicate a particular symbol, for example the letter A, or the ampersand symbol (&), and so on. Further, the individually addressable and writable elements 106 of each key 102 may all have the same shape or different shapes, or have groupings of different shapes or colors.

Depending on the density of the individually writable elements 106, surface 104 can be configured to display multiple signals simultaneously, the top symbol indicating the ampersand and the bottom symbol indicating the numeral 7 for one key 102 for instance. The multiple symbols can be displayed side-by-side or in any other arrangement as well. Thus generally each key 102 is configurable to display multiple symbols, and this can be simultaneously (side-by-side or top-bottom for instance) or it can be non-simultaneously—that is, display first symbol (or combination of symbols) for a period of time, then display a second symbol (or combination) for another period of time. In the case of combinations of symbols, the first combination may have some or no symbols in common with the second combination of symbols displayed on each key.

The individually addressable and writable elements 106 of each key 102 can be in the form of LEDs, pixels of an LCD display, elements of electrophoretic ink (E ink)™ such as that used in e-readers, and the like. The signals to individually select each element 106 can be provided via input I, which in this case would be a bundle of connections each corresponding to an individual element 106. Alternatively, as shown in FIG. 1a, each key 102 can be provided with its own memory 108 in which are stored, for each symbol to be displayed, an activation combination relating to the combination of elements 106 that need to be activated. The memory is then addressed by write signals received by key 102 at input connection I. In response, the memory outputs, via I′, the particular combination of activation signals for the corresponding elements 106 that are necessary to display the selected symbol.

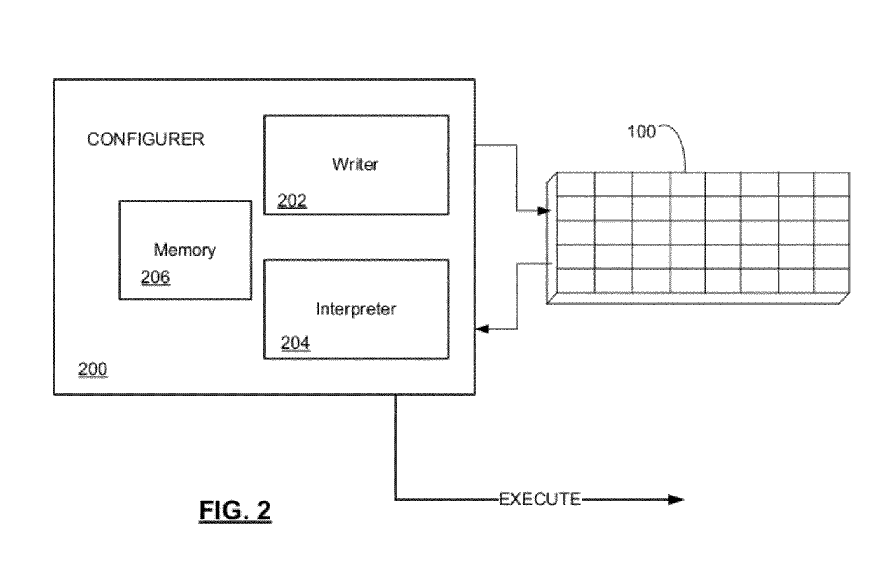

FIG. 2 is a block diagram showing a system for selectively configuring a keyboard such as keyboard 100 described above. A configurer module 200, which can be a hardware or a software component or a combination of these, includes a writer 202 and a function interpreter 204. Writer 202 is operative to selectively provide to each key of multiple keys 102 of keyboard 100 a set of activation signals that individually address the writable elements 106 of that key. Alternatively, writer 202 can communicate with a memory 108 (FIG. 1a) of each key 102, instructing the memory to select the proper combination of elements 106 to activate in order to display a desired character or symbol. Each key of the multiple keys 102 is thus individually selected and configured to display on surface 104 thereof one or more graphical symbols for viewing by a user. The symbols or characters can be letters of any of myriad languages, or punctuation marks or any other indicia that are representable on keyboards.

Configurer 200 also includes a function interpreter 204 in communication with the individual keys 102 of keyboard 100. Based on the activation state of each key 102, a signal is issued for execution by the processor (not shown) of the host computer, which as explained above, may be a desktop computer, a laptop computer, PDA, cellular telephone or smart phone, or the like. Depending on the language or the functionality with which the configurer 200 is associated, activation for example of the third top key of keyboard 100 may execute displaying the English letter C on a screen (not shown) of the computer, or a different symbol of a different language, or it may activate a microprogram in the software of the host device, or generate any action that can be triggered by a keyboard key. Typically, the displayed marking on the activated key, as set by writer 202 and implemented directly through input I or indirectly through memory 108 and input I′, would correspond in some way to the action that is executed so that user could readily identify the functionality associated with that particular key.

Configurer module 200 is not necessarily resident on the host device. In one embodiment, it comprises code or hardware that is stored in a portable device that can be mated to different host devices. For example, it can be disposed on a memory device, such as a USB memory stick, that can be coupled to different host devices. Such a portable arrangement would enable a user to for example travel from one country to another, porting the configurer module 200 associated with the language of his/her origin country along to the new destination, possibly with a reconfigurable keyboard 100, for use there, thereby avoiding having to use an unfamiliar keyboard layout at the destination country.

In addition, configurer 200 is not confined to a single keyboard layout. In one embodiment, it has multiple settings, each for instance associated with a particular language, and the user can select a specific setting that results in a specific keyboard layout. For example, one selectable setting would correspond to the English language, another would correspond to German, and so on. Selection of the English language setting would cause the configurer 200 to issue, through the writer 202, write signals to keys 102 of the keyboard that would result in display of a conventional English language keyboard layout, and would cause function interpreter 204 to interpret activation of the keys as a function of the selected setting. Each setting, including the associated write signals issued by writer 202 and corresponding interpretation schema utilized by interpreter 204, can be stored in a memory 206. Configurer 200 then, in a portable configuration, can be taken to several different regions for adaption of reconfigurable keyboards appropriately.

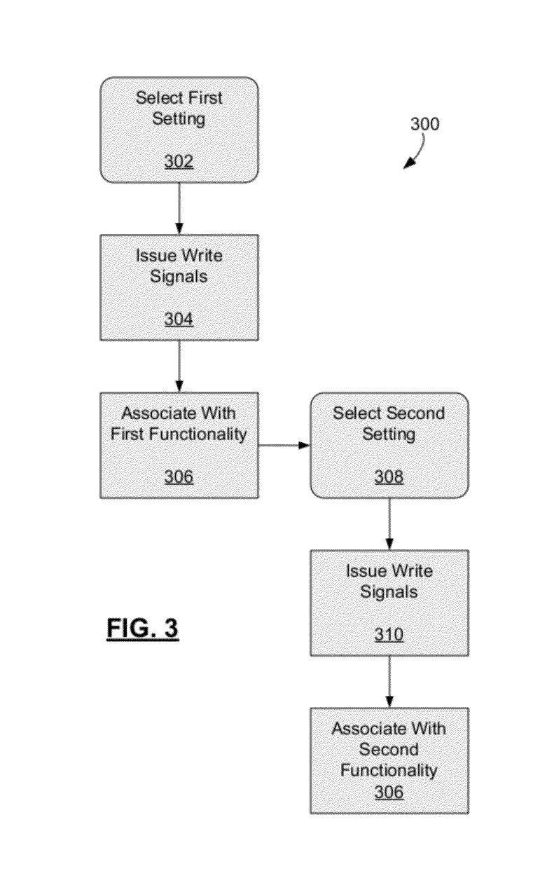

FIG. 3 is a flow diagram of a method 300 for selectively configuring the operation of a keyboard having electronically writable keys. The method includes, at 302, selecting a first setting, issuing write signals, at 304, to a first set of one or more keys of the keyboard that cause each key of the first set to display at least one symbol that is a function of the first setting, associating, at 306, activation of the keys of the first set with a first functionality of the keyboard that is a function of the first setting, selecting, at 308, a second setting, issuing write signals, at 310, to the first set of one or more keys of the keyboard that cause each key of the first set to display at least one symbol that is a function of the second setting, and associating, at 312, activation of the keys of the first set with a second functionality of the keyboard that is a function of the second setting.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A reconfigurable keyboard comprising:
one or more input connections; and
one or more electronically writable keys each coupled to a corresponding input connection and each having a display surface operative to display a plurality of symbols simultaneously or non-simultaneously based on a write signal received at the corresponding input connection.

2. The reconfigurable keyboard of claim 1, wherein each of the one or more electronically writable keys includes an associated memory configured to receive the write signal.

3. The reconfigurable keyboard of claim 1, wherein each associated memory is configured to store multiple activation combinations, each activation combination corresponding to a symbol to be displayed on a display surface of a key with which the memory is associated.

4. A configurer for configuring a reconfigurable keyboard having one or more input connections and one or more electronically writable keys each coupled to a corresponding input connection and each having a display surface operative to display a plurality of symbols simultaneously or non-simultaneously based on a write signal received at the corresponding input connection, the configurer comprising:
a memory operative to store one or more settings;
a writer operative to issue write signals to input connections of the keys of the reconfigurable keyboard as a function of a selected one of the one or more settings; and
an interpreter operative to interpret activation of keys of the reconfigurable keyboard as a function of the selected one of the one or more settings.

5. The configurer of claim 4, said configurer being housed in a portable device.

6. A system comprising:
a reconfigurable keyboard including:
one or more input connections; and
one or more electronically writable keys each coupled to a corresponding input connection and each having a display surface operative to display a plurality of symbols simultaneously or non-simultaneously based on a write signal received at the corresponding input connection; and
a configurer including:
a memory operative to store one or more settings;
a writer operative to issue write signals to input connections of the keys of the reconfigurable keyboard as a function of a selected one of the one or more settings; and
an interpreter operative to interpret activation of keys of the reconfigurable keyboard as a function of the selected one of the one or more settings.

7. The system of claim 6, wherein the configurer is housed in a portable device.

8. A method for selectively configuring the operation of a keyboard having electronically writable keys, the method comprising:
selecting a first setting;
issuing to a first set of one or more keys of the keyboard write signals that cause each key of the first set to display at least one symbol that is a function of the first setting;
associating activation of the keys of the first set with a first functionality of the keyboard that is a function of the first setting;
selecting a second setting;
issuing to the first set of one or more keys of the keyboard write signals that cause each key of the first set to display at least one symbol that is a function of the second setting; and
associating activation of the keys of the first set with a second functionality of the keyboard that is a function of the second setting.
